(19) United States
(12) Patent Application Publication
(10) Pub. No.: US 2025/0379059 A1
(43) Pub. Date: Dec. 11, 2025

(54) METHOD OF BOTTOM REACTION EFFICIENCY MODULATION FOR ALD AND ALE

(71) Applicant: Applied Materials, Inc., Santa Clara, CA (US)

(72) Inventors: Le ZHANG, Santa Clara, CA (US); Chih-Hsun HSU, Santa Clara, CA (US); David T. OR, Santa Clara, CA (US); Jiang LU, Milpitas, CA (US)

(21) Appl. No.: 19/226,495

(22) Filed: Jun. 3, 2025

Related U.S. Application Data
(60) Provisional application No. 63/658,313, filed on Jun. 10, 2024.

(51) Int. Cl. H01L 21/3065; H01L 21/02

(52) U.S. Cl. CPC H01L 21/3065; H01L 21/02068

(57) ABSTRACT

Embodiments described herein provide methods for atomic layer deposition and atomic layer etching of high aspect ratio structures. In some embodiments, a pulsed gas dilution method is provided. The method includes providing a substrate, the substrate includes a cavity, the cavity having a first surface and a second surface, where the first surface is disposed below the second surface in the cavity. The method includes supplying a first gas, pulsing a second gas at a high pressure, and creating a concentration gradient where there is a higher concentration of the first gas at the first surface of the cavity.

### CROSS-REFERENCE TO RELATED APPLICATIONS

This application claims benefit of U.S. Provisional patent application Ser. No. 63/658,313, filed Jun. 10, 2024, which is herein incorporated by reference in its entirety.

### FIELD

Embodiments of the present principles generally relate to methods for forming low resistivity contacts for semiconductor device formation.

### BACKGROUND

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal-oxide-semiconductor field-effect transistor) devices.

An example of finFET or MOSFET device includes a gate electrode on a gate dielectric layer on a surface of a semiconductor substrate. Source/drain regions are provided along opposite sides of the gate electrode. The source and drain regions are generally heavily doped regions of the semiconductor substrate. Usually, a silicide layer, for example, a titanium silicide layer, is required to form a reliable contact at the formed source and drain regions.

In a traditional middle-end-of-the-line (MEOL) contact junction formation process, a feature also referred to as a cavity, a via, or a trench, is fabricated in the semiconductor substrate. MEOL contact junctions allow connections between front-end-of-the-line (FEOL) semiconductor structures and back-end-of-the-line (BEOL) interconnects. Contacts with a low resistivity are desirable in semiconductor devices. However, when MEOL contacts have high resistance, the contacts produce poor connections between the FEOL structures and the BEOL packaging interconnects, reducing the performance of the packaged semiconductor structures.

With the growing complexity of semiconductors and thus MEOL contacts, there is a need for methods that selectively modify the bottom surface of high aspect ratio (HAR) structures. However, conventional isotropic etch (and deposition) methods can at most provide a bottom etch amount (EA) to top EA ratio of 1:1 in high aspect ratio structures due to the fundamental limitation of the isotropic distribution of reactive etch gases.

There is a need for improved methods that precisely control the bottom reaction efficiency of atomic layer deposition and atomic layer etching applications in high aspect ratio semiconductor structures.

### SUMMARY

Embodiments of the present principles generally relate to forming low resistivity contacts for semiconductor device formation. More particularly, embodiments described herein provide methods for atomic layer deposition and atomic layer etching of high aspect ratio structures (HARS).

In some embodiments, a pulsed gas dilution method is provided. The method includes providing a substrate including a cavity, the cavity having a first surface and a second surface, where the first surface is disposed below the second surface in the cavity. The method includes supplying a first gas, pulsing a second gas at a high pressure, and creating a concentration gradient where there is a higher concentration of the first gas at the first surface of the cavity.

In some embodiments, a method for precleaning a surface of a contact structure is provided. The method includes providing a substrate into a processing chamber, the substrate includes a cavity, the cavity having a first surface and a second surface, where the first surface includes silicon and is disposed below the second surface in the cavity. The method includes supplying a first gas, pulsing a second gas at a pressure of about 150 Torr to about 350 Torr with a duration of about 0.2 seconds to about 0.7 seconds, creating a concentration gradient wherein there is a higher concentration of the first gas at the first surface of the cavity, and etching the first surface of the cavity.

In some embodiments, a method for precleaning a surface of a contact structure includes providing a substrate, the substrate including a cavity, the cavity having a first surface and a second surface, where the first surface includes silicon and is disposed below the second surface in the cavity. The method includes supplying a first gas, stopping the supply of the first gas, pulsing a second gas at a pressure of about 150 Torr to about 350 Torr with a duration of about 0.2 seconds to about 0.7 seconds, where stopping the supply of the first gas and pulsing the second gas occur simultaneously, creating a concentration gradient where there is a higher concentration of the first gas at the first surface of the cavity, and etching the first surface of the cavity. Etching the first surface of the cavity has a bottom cleaning efficiency of greater than 100%.

In some embodiments, a method for precleaning a surface of a contact structure includes providing a substrate, the substrate including a cavity, the cavity having a first surface and a second surface, where the first surface comprises silicon and is disposed below the second surface in the cavity. The method includes supplying a first gas to reach a steady chamber pressure of about 1 Torr to about 5 Torr, stopping the supply of the first gas, pulsing a second gas, creating a concentration gradient where there is a higher concentration of the first gas at the first surface of the cavity, and etching the first surface of the cavity. Where stopping the supply of the first gas and pulsing the second gas occur simultaneously, and the chamber pressure increases by about 30% to about 50% while pulsing the second gas. Etching the first surface of the cavity has a bottom cleaning efficiency of greater than 100%.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1A is a cross-section view of a portion of a semiconductor structure, in accordance with some embodiments.

FIG. 1B is a cross-section view of a portion of a semiconductor structure, in accordance with some embodiments.

FIG. 1C is a cross-section view of a portion of a semiconductor structure, in accordance with some embodiments.

FIG. 2 is a schematic block diagram of a pulsed gas dilution method, in accordance with some embodiments.

FIG. 3A is a gas flow diagram of a pulsed gas dilution method, in accordance with some embodiments.

FIG. 3B is a gas flow diagram of a pulsed gas dilution method, in accordance with some embodiments.

FIG. 3C is a gas flow diagram of a pulsed gas dilution method, in accordance with some embodiments.

FIG. 4 is a schematic cross-sectional view of one embodiment of a process chamber, in accordance with one or more aspects of the disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present principles generally relate to methods for forming low resistivity contacts for semiconductor device formation. More particularly, embodiments described herein provide methods for atomic layer deposition and atomic layer etching of high aspect ratio structures (HARS). It has been discovered that the pulsed gas dilution methods described herein can preferentially alter, whether by etching or deposition, the bottom surfaces or regions of HARS over the top surface of HARS. For example, some embodiments include a pulsed gas dilution etch method with a bottom cleaning efficiency (e.g., the etch amount of the bottom/etch amount of the top of the HARS) of greater than 100%.

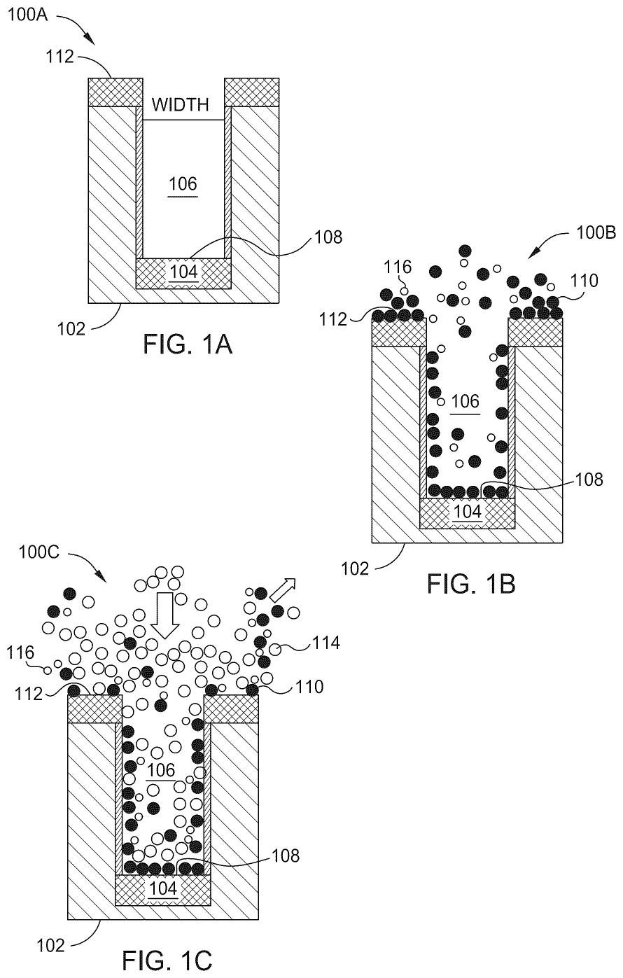

FIG. 1A, is a schematic illustration of a high aspect ratio contact structure according to one or more embodiments described herein. The contact structure 100 has a top surface 112 and a bottom surface 108. The bottom surface 108 is located within the high aspect ratio cavity 106. Conventional isotropic etch (and deposition) methods can at most provide a bottom etch amount to top etch amount ratio of 1:1 in HARS, such as the contact structure 100, due to the fundamental limitation of the isotropic distribution of reactive etch gases. In contrast, the pulsed gas dilution methods described herein can preferentially etch the bottom surface 108 of contact structure 100 to achieve a bottom etch amount to top etch amount ratio of greater than 1:1 by modulating the concentration of the etchant at the bottom surface 108.

### Process Examples

The methods of the present disclosure can be effective for MEOL metal gapfill processes in general and may be applied to both atomic layer etching and atomic layer deposition processes. For the sake of brevity, the methods discussed in detail relate to an atomic layer etching process. However, they could also be applied to an atomic layer deposition process. In one example, an atomic layer etching process can include a preclean process performed prior to the performance of an atomic layer deposition process, wherein the preclean process is adapted to remove oxides and other contaminants formed on a surface of a contact within the contact structure 100.

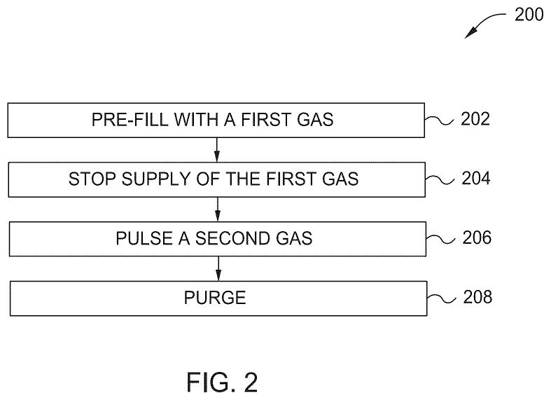

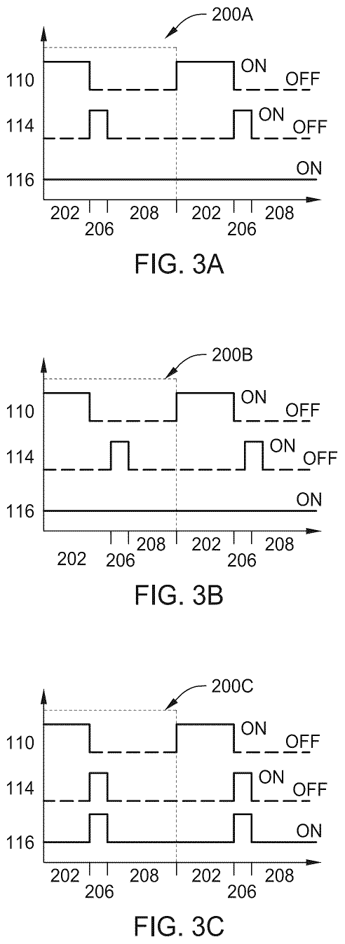

In the method 200 of FIG. 2, a pulsed gas dilution method is used to preferentially react two or more gases at the bottom of a high aspect ratio structure. In the discussion of the method 200, references will be made to the views of FIGS. 1A-1C and FIGS. 3A-3C. In one or more embodiments, the method 200 is used to preferentially etch the bottom of a high aspect ratio structure. As discussed above, in some embodiments, method 200 is a preclean process that is performed to remove any contaminants and/or oxidation from surfaces of a contact structure 100 as depicted in FIGS. 1A-1C. The contact structure 100 has a silicon-based portion 104 that is exposed in a cavity 106 formed within a dielectric material layer (e.g., silicon dioxide, silicon nitride, etc.) formed on a substrate 102. In some embodiments, the silicon-based portion 104 may be a silicon (Si) material or a silicon germanium (SiGe) material.

In one or more embodiments, cavities (e.g., vias) can have an average width. For example, cavity 106 can have a width (shown in FIG. 1A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 106 can have an aspect ratio (depth:width) of about 1:1 to about 100:1, such as about 10:1, 15:1, or 25:1 to about 35:1, 45:1, or 50:1.

In block 202 of method 200, a pre-fill (pPF) operation is performed to evenly distribute a first gas 110 (depicted as black circles in FIGS. 1B-1C) throughout the chamber and around the substrate 102. The first gas 110 and a dilution gas 116 are supplied into the chamber and allowed to equilibrate around the substrate 102, such that the concentration of the first gas 110 is equal at the top surface 112 of the substrate 102 and within the cavity 106 of the substrate 102, as shown in FIG. 1B. The dilution gas may include a noble gas, such as argon (Ar), neon (Ne), and helium (He), and combinations thereof. In one or more embodiments, the first gas 110 may be an etchant precursor gas, such as a fluorine containing gas, for example, hydrogen fluoride (HF). Without being bound by theory, it is believed that the equal distribution of the first gas 110 around the substrate 102 provides an equal adsorption of the first gas 110 on the silicon of both the top surface 112 of the substrate 102 and the bottom surface 108 of the cavity 106.

In one or more embodiments, the first gas is continuously supplied with the dilution gas at a constant flow rate with a ratio of first gas:dilution gas of about 1:1 to about 1:4 to reach a steady chamber pressure in the range of about 1 Torr to about 5 Torr.

In block 204, the supply of the first gas 110 is stopped while maintaining the flow of the dilution gas 116.

In block 206, a second gas, 114, is pulsed into the chamber. In one or more embodiments, the second gas is an etchant precursor gas, such as ammonia. The first gas 110 and the second gas 114 react to form the target reactive species, such as an etchant gas. In one example, the first gas 110 comprises hydrogen fluoride (HF), and the second gas 114 comprises ammonia (NH₃), and the combination of the gases forms a reactive species comprising ammonium fluoride (NH₄F).

In one or more embodiments, a large amount of the second gas 114 is supplied in a pressurized short pulse. The gas pulse may have a duration of about 0.2s to about 0.7s and a high pressure greater than about 150 Torr, such as about 150 Torr to about 350 Torr. During the pulsing step (206), the chamber pressure may be increased by about 30% to about 50% of the total pressure during the pPF operation (202). The high pressure flow of the second gas 114 has a twofold effect, shown in FIG. 1C. Firstly, the second gas 114 purges and dilutes the first gas 110 adsorbed to the top surface 112. Secondly, the high pressure flow prevents the first gas 110 from diffusing out of the cavity 106. Without being bound by theory, it is believed that the large supply of the second gas 114 competes for the silicon adsorption positions on the top surface 112, resulting in a faster desorption of the first gas from the top surface 112 than the bottom surface 108. The difference in desorption rates of the first gas 110 creates a concentration gradient with a higher concentration of the first gas 110 at the bottom surface 108 of the cavity 106 and a lower concentration of the first gas 110 at the top surface 112. The higher concentration of the first gas 110 at the bottom surface 108 results in a higher concentration of the etchant at the bottom surface 108, allowing for a greater etch amount (EA) at the bottom surface 108.

In block 208, the chamber is purged of the first gas 110 and the second gas 114 by the continuous flow of the dilution gas 116. The method may then be repeated starting at block 202 at least one additional time. In some embodiments, the bottom cleaning efficiency (BCE %) may be tuned by altering the pressure of the pulsed second gas. For example, which is non-limiting, the BCE % may be tuned between about 77% and about 108% by changing the pressure of the pulsed second gas in a range of about 150 Torr to about 350 Torr. Higher-pressure pulses of the second gas result in higher BCE %. For example, in at least one embodiment, the second gas is pulsed at a pressure of about 150 Torr, resulting in a BCE % of about 77% to about 98%. In another embodiment, the second gas is pulsed at a pressure of about 250 Torr, resulting in a BCE % of about 96% to about 108%. In another embodiment, the second gas is pulsed at a pressure of about 350 Torr, resulting in a BCE % of about 105% to about 108%. Due to the limited nature of adsorption, the BCE % is less sensitive to cavity dimensions reduction than changes in the pressure of the pulsed second gas.

In some embodiments, the operations of blocks 204 and 206 are performed simultaneously, such that the supply of the first gas 110 is stopped as the supply of the second gas 114 begins, as depicted in FIG. 3A (method 200A). In other embodiments, there is a delay between the operations of block 204 and block 206. For example, the supply of the first gas 110 is stopped, and there is a predetermined period of time in the range of about 10 ms to about 25 ms before the supply of the second gas 114 begins, as depicted in FIG. 3B (method 200B). The delay between stopping the supply of the first gas 110 and pulsing the second gas 114 while maintaining the flow of the dilution gas 116 further dilutes the first gas 110 resulting in a more drastic concentration gradient of the first gas 110 between the top surface 112 and the bottom surface 108, resulting in a BEC % greater than 100%, such as about 120% to about 200%. In both methods 200A and 200B, the dilution gas 116 is continuously supplied at a constant flowrate. In some embodiments, the dilution gas 116 is pulsed in conjunction with the second gas 114, such that the dilution gas is supplied at a first flowrate while the first gas 110 is supplied and the chamber is purged and at a second higher flow rate when the second gas is pulsed, as depicted in FIG. 3C (method 200C). The dilution gas may be pulsed with the second gas at a pressure that is about 30% to about 100% of the pressure of the second gas pulse. The increase in flowrate of the dilution gas 116 during the pulsing of the second gas 114 further dilutes the first gas 110, resulting in a more drastic concentration gradient of the first gas 110 between the top surface 112 and the bottom surface 108, resulting in a BEC % greater than 100%.

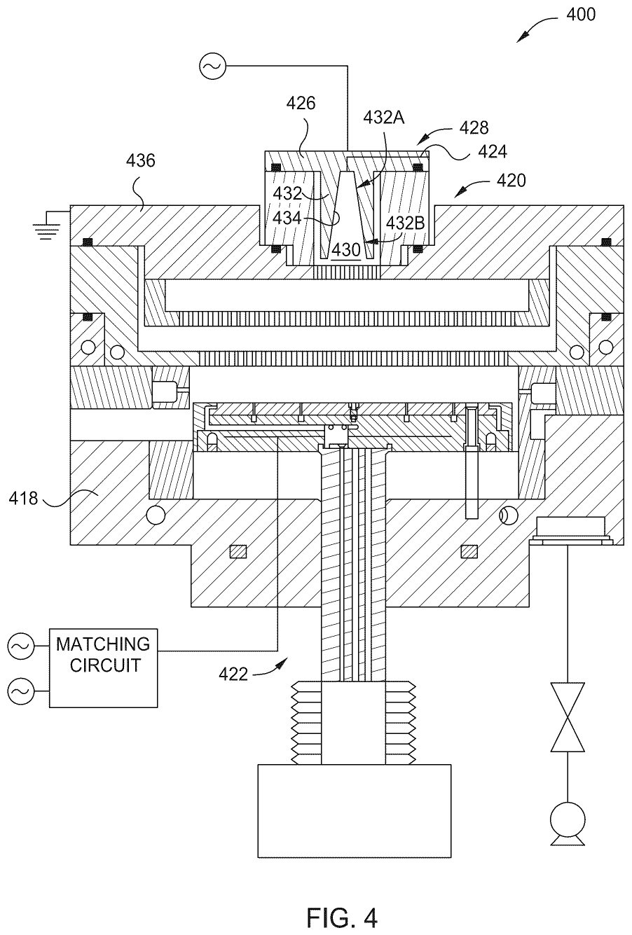

The methods of the present disclosure may be performed in any suitable processing chamber capable of supplying an individual high pressure gas pulse. FIG. 4 is a cross-sectional view of an illustrative processing chamber 400 suitable for conducting etching processes, such as the etching process described above. The chamber 400 is configured to remove materials from a material layer disposed on a substrate surface. The chamber 400 is particularly useful for performing the plasma assisted dry etch process. Examples of processing chambers 400 suitable for practicing the disclosed methods include a Siconi™ processing chamber and an Exsel™ chamber, which are available from Applied Materials, Santa Clara, California. It is noted that other vacuum processing chambers available from other manufacturers may also be adapted to practice the present disclosure.

The processing chamber 400 provides both heating and cooling of a substrate surface without breaking vacuum. In one embodiment, the processing chamber 400 includes a chamber body 418, a lid assembly 420, and a support assembly 422. The lid assembly 420 is disposed at an upper end of the chamber body 418, and the support assembly 422 is at least partially disposed within the chamber body 418.

In one or more embodiments, the lid assembly 420 includes one or more gas inlets 424 (only one is shown) that are at least partially formed within an upper section 426 of the first electrode 428. The one or more process gases enter the lid assembly 420 via the one or more gas inlets 424. The one or more gas inlets 424 are in fluid communication with the cavity 430 at a first end thereof and coupled to one or more upstream gas sources and/or other gas delivery components, such as gas mixers, at a second end thereof. The cavity 430 can include an expanding section 432 that bounds the cavity 430, that is disposed over a substrate.

In one or more embodiments, it is desirable for the processes described above in relation to method 200 to be performed using a thermal non-plasma processes. However, in one or more embodiments, a first electrode 428 includes the expanding section 432 that bounds the cavity 430. In one or more embodiments, the expanding section 432 is an annular member that has an inner surface or diameter 434 that gradually increases from an upper portion 432A thereof to a lower portion 432B thereof. As such, the distance between the first electrode 428 and a second electrode 436 is variable across the expanding section 432. The varying distance helps control the formation and stability of the plasma generated within the cavity 430.

The expanding section 432 is in fluid communication with the gas inlet 424 as described above. The first end of the one or more gas inlets 424 can open into the cavity 430 at the upper most point of the inner diameter of the expanding section 432. Similarly, the first end of the one or more gas inlets 424 can open into the cavity 430 at any height interval along the inner diameter 434 of the expanding section 432. Although not shown, two gas inlets 424 can be disposed at opposite sides of the expanding section 432 to create a swirling flow pattern or “vortex” flow into the expanding section 432, which helps mix the gases within the cavity 430.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values, are contemplated unless otherwise indicated. Certain lower limits, upper limits, and ranges appear in one or more claims below. All numerical values are “about” or “approximately” the indicated value, and take into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

While the foregoing is directed to embodiments of the present principles, other and further embodiments of the principles may be devised without departing from the basic scope thereof.

1. An etching method comprising:
providing a substrate, wherein the substrate comprises a cavity, the cavity comprising a first surface and a second surface, wherein the first surface is disposed below the second surface in the cavity;
supplying a first gas;
pulsing a second gas at a high pressure; and
creating a concentration gradient wherein there is a higher concentration of the first gas at the first surface of the cavity.

2. The method of claim 1, further comprising providing a dilution gas while providing the first gas and pulsing the second gas.

3. The method of claim 1, further comprising stopping the supply of the first gas and pulsing the second gas simultaneously.

4. The method of claim 1, further comprising stopping the supply of the first gas and after a predetermined period of time pulsing the second gas.

5. The method of claim 2, further comprising stopping the supply of the first gas and pulsing the second gas and the dilution gas simultaneously.

6. The method of claim 2, wherein
the first surface comprises silicon;
the first gas comprises a fluorine containing gas; and
the second gas comprises ammonia.

7. The method of claim 2, wherein
the first surface comprises silicon;
the first gas comprises a fluorine containing gas and the dilution gas; and
the second gas comprises ammonia and the dilution gas.

8. The method of claim 1, wherein the second gas is pulsed at a pressure of about 150 Torr to about 350 Torr.

9. The method of claim 1, wherein the second gas is pulsed with a duration of about 0.2 seconds to about 0.7 seconds.

10. The method of claim 1, wherein the first gas is provided at a pressure of about 1 Torr to about 5 Torr.

11. A method for precleaning a surface of a contact structure comprising:
providing a substrate into a processing chamber, the substrate comprising a cavity, the cavity comprising a first surface and a second surface, wherein the first surface comprises silicon and is disposed below the second surface in the cavity;
supplying a first gas;
pulsing a second gas at a pressure of about 150 Torr to about 350 Torr with a duration of about 0.2 seconds to about 0.7 seconds;
creating a concentration gradient wherein there is a higher concentration of the first gas at the first surface of the cavity; and
etching the first surface of the cavity.

12. The method of claim 11, further comprising providing a dilution gas while providing the first gas and pulsing the second gas.

13. The method of claim 12, wherein a ratio of the first gas to the dilution gas is about 1:1 to about 1:4.

14. The method of claim 11, further comprising stopping the supply of the first gas and after about 10 ms to about 25 ms pulsing the second gas.

15. The method of claim 12, further comprising stopping the supply of the first gas and pulsing the second gas and the dilution gas simultaneously.

16. The method of claim 12, wherein
the first surface comprises silicon;
the first gas comprises a fluorine containing gas; and
the second gas comprises ammonia.

17. The method of claim 12, wherein the pressure inside the process chamber increases by about 30% to about 50% when pulsing the second gas.

18. The method of claim 11, wherein the first gas and the second gas react to form an etchant.

19. The method of claim 11, wherein a ratio of an etch amount of the first surface to an etch amount of the second surface is greater than 1:1.

20. A method for precleaning a surface of a contact structure comprising:
providing a substrate, the substrate comprising a cavity, the cavity comprising a first surface and a second surface, wherein the first surface comprises silicon and is disposed below the second surface in the cavity;
supplying a first gas to reach a steady chamber pressure of about 1 Torr to about 5 Torr;
stopping the supply of the first gas;
pulsing a second gas, wherein stopping the supply of the first gas and pulsing the second gas occur simultaneously, and the chamber pressure increases by about 30% to about 50% while pulsing the second gas;
creating a concentration gradient wherein there is a higher concentration of the first gas at the first surface of the cavity; and
etching the first surface of the cavity, wherein etching the first surface of the cavity has a bottom cleaning efficiency of greater than 100%.
